(19) United States
(12) Patent Application Publication
(10) Pub. No.: US 2008/0078948 A1
(43) Pub. Date: Apr. 3, 2008

(54) PROCESSING TERMINATION DETECTION METHOD AND APPARATUS

(75) Inventor: Susumu SAITO, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/859,971

(22) Filed: Sep. 24, 2007

Related U.S. Application Data
(60) Provisional application No. 60/883,246, filed on Jan. 3, 2007.

(30) Foreign Application Priority Data
Oct. 3, 2006 (JP) 2006-271673

(51) Int. Cl. H01L 21/66; H01L 21/67

(52) U.S. Cl. 250/492.2; 438/7; 257/E21.53

(57) ABSTRACT

A processing termination detection method capable of accurately performing changeover of etch rates when a residual film thickness of a to-be-processed layer decreases to a predetermined value. A substrate processing apparatus starts first etching to form a through-hole in a single crystal silicon layer of a wafer. A processing termination detection apparatus irradiates laser light comprised of red to near-infrared light onto the wafer and performs a frequency analysis of reflected light received from the wafer. When the intensity, represented in a result of the frequency analysis, in a frequency band corresponding to residual layer interference light has exceeded a threshold value, second etching is started to remove a through hole formation portion of the single crystal silicon layer to cause a silicon oxide layer to be exposed.

### BACKGROUND OF THE INVENTION

1. Field of the Invention

The present invention relates to processing termination detection method and apparatus, and more particularly, to processing termination detection method and apparatus for detecting a termination point of etching on a substrate.

2. Description of the Related Art

Three-dimensional mounting is recently becoming a mainstream of semiconductor device packaging technology, in which a plurality of chips are mounted in layers. In the three-dimensional mounting, an SOI (silicon-on-insulator) substrate is frequently used, which is comprised of a single crystal silicon layer S, a silicon oxide layer O, and a single crystal silicon layer P, as shown in FIG. 10, and in which a resist layer R is formed in a predetermined pattern on the silicon layer P.

For the three-dimensional mounting, a through-hole H is formed by etching in the SOI substrate, and Cu or the like is filled into the through-hole H for chip connection. However, if the single crystal silicon layer P is excessively etched in the formation of the through-hole H in the silicon layer P, the silicon layer P is completely removed and the silicon oxide layer O is exposed. In that case, a side surface of the through-hole H is etched and a notch N is formed therein.

In order to prevent undesired formation of the notch N, the single crystal silicon layer P must be etched with a low etch rate to suppress the side surface of the through-hole H from being etched after exposure of the silicon oxide layer O. However, such etching condition results in low throughput.

To obviate this, in the formation of the through-hole H, it is necessary to etch the single crystal silicon layer P in a high etch rate condition (first etching step), and etch the remaining silicon layer P in a low etch rate condition (second etching step) after a residual film thickness of the silicon layer P on the silicon oxide layer O decreases to a predetermined value. Moreover, it is necessary to immediately stop the etching when the silicon oxide layer O is exposed.

To determine the residual film thickness of the single crystal silicon layer P, a conventional method measures a time period elapsed from the start of etching of the silicon layer P, and upon elapse of a predetermined time period, estimates that the residual film thickness becomes less than a predetermined value. However, the estimation of this method cannot accurately determine that the single crystal silicon layer P has been etched to have the predetermined residual film thickness of the single crystal silicon layer P, thus making it difficult to perform changeover from the high etch rate condition to the low etch rate condition in proper timing.

Another method has been developed that utilizes a phenomenon that when a residual film thickness of a to-be-etched layer becomes thin, light can pass through the to-be-etched layer and is reflected by a surface of an underlayer. Specifically, this method irradiates light toward the surface of the to-be-etched layer, causes interference light to be produced between reflected light from the surface of the to-be-etched layer and reflected light from the surface of the underlayer, and determines that the residual film thickness of the to-be-etched layer becomes less than a predetermined thickness when the intensity of the interference light becomes stronger than a predetermined intensity (see, for example, Japanese Laid-open Patent Publication No. 2001-85388). This method has frequently been employed for formation of a gate in the vicinity of a transistor. In this method, a residual film of several ten nms to several hundred nms is detected using a UV radiation or visible light of a relatively short wavelength.

However, the etching rate in the first etching step for formation of the through-hole H in the SOI substrate is extremely high such as from 10 μm/min to 50 μm/min. Thus, if the above described method for residual film thickness detection is applied to the formation of a through-hole H, a time period from when the predetermined residual film thickness (for example, 100 nm) is detected to when the silicon oxide layer O becomes exposed is extremely short (for example, 0.12 to 0.6 seconds). This makes it difficult to carry out a proper changeover from the first etching step to the second etching step (etch rate changeover). A delay is not permissible in the detection of when the predetermined residual film thickness is reached, and the changeover from the first etching step to the second etching step must be made extremely rapidly. However, the etching rate in the first etching step can vary, and therefore, the silicon oxide layer O can sometimes be exposed. To obviate this, it is preferable that a residual film thickness of several μms be detected.

The through-hole H is deep in depth and small in aperture rate. A major component of reflected light passing through the through-hole H is not comprised of interference light between reflected light from a surface of a through-hole formation portion (shown at Ph in FIG. 2) of the single crystal silicon layer P and reflected light from a surface of the silicon oxide layer O, but comprised of interference light between reflected light from a surface of the resist layer R and reflected light from the surface of the through-hole formation portion of the silicon layer P. With the method proposed in Japanese Patent Laid-open No. 2001-85388, it is difficult to accurately monitor the interference light between the reflected light from the surface of the through-hole formation portion of the silicon layer P and the reflected light from the surface of the silicon oxide layer O.

For the above described reason, the etch rate cannot accurately be changed when the residual film thickness of the single crystal silicon layer P decreases to a predetermined value.

### SUMMARY OF THE INVENTION

The present invention provides processing termination detection method and apparatus capable of accurately performing changeover of etch rates when a residual film thickness of a to-be-processed layer decreases to a predetermined value.

According to a first aspect of the present invention, there is provided a processing termination detection method for use in forming a process hole in a to-be-processed layer of a substrate comprised of at least an underlayer, the to-be-processed layer, and a mask layer, which are formed in layers in this order, comprising an irradiation step of irradiating light of long wavelength onto the substrate, a light reception step of receiving reflected light from surfaces of at least the to-be-processed layer, the underlayer, and the mask layer of the substrate, a frequency analysis step of performing a frequency analysis of a waveform of received reflected light, an intensity determination step of determining whether an intensity at a predetermined frequency represented in a result of the frequency analysis exceeds a predetermined threshold value, and a processing rate changeover step of changing a processing rate of the to-be-processed layer when it is determined that the intensity at the predetermined frequency exceeds the predetermined threshold value.

In the processing termination detection method of this invention, reflected light is received from surfaces of various layers of a substrate onto which light of long wavelength is irradiated, and a waveform of the received reflected light is subjected to frequency analysis. When the intensity at a predetermined frequency represented in a result of the frequency analysis exceeds a predetermined threshold value, the processing rate of a to-be-processed layer is changed.

The to-be-processed layer has a smaller light absorption coefficient for transmission light passing therethrough of longer wavelength. In the case of transmission light of long wavelength, therefore, even when a residual film thickness of the to-be-processed layer still has a somewhat large value in the order of several μms, interference is produced between reflection light from a surface of a process hole formation portion of the to-be-processed layer and reflected light passing through the to-be-processed layer and reflected from a surface of an underlayer. In other words, it is possible to detect that the residual film thickness of the to-be-processed layer has decreased to several μms.

Pieces of reflected light from surfaces of various layers of the substrate such as the underlayer, to-be-processed layer, and mask layer interfere with one another to produce pieces of interference light. In the formation of the process hole, thicknesses of the to-be-processed layer and the mask layer vary with elapse of time. Thus, optical path lengths of the pieces of reflected light vary, so that the intensities of pieces of interference light periodically vary. Since there is a difference in a film thickness change rate between the to-be-processed layer and the mask layer, the period (frequency) of a change in intensity is different between pieces of interference light. In other words, pieces of interference light having different frequencies are superimposed on reflected light. A frequency analysis of a waveform of the reflected light makes it possible to separate and monitor the interference light between the reflected light from the surface of the process hole formation portion of the to-be-processed layer and the reflected light from the surface of the underlayer.

Therefore, it is possible to accurately perform changeover of etch rates when the residual film thickness of the to-be-processed layer becomes smaller than a predetermined value.

The processing termination detection method can include a differentiation step of taking a second-order derivative of the waveform of the received reflected light after the processing rate is changed, a derivative value determination step of determining whether a variation in a value of the second-order derivative falls within a predetermined range, and a processing termination step of stopping processing on the to-be-processed layer when it is determined that the variation in the value of the second-order derivative falls within the predetermined range.

With the above detection method, after the change of the processing rate, a second-order derivative of a waveform of received reflected light is taken. When a variation in second-order derivative value falls within a predetermined range, processing on the to-be-processed layer is stopped. When the to-be-processed layer is completely removed and a film thickness change rate thereof becomes equal to zero, there appears in the reflected light waveform only a waveform of interference light between reflected light from a surface of the mask layer and reflected light from a surface of the to-be-processed layer covered by the mask layer. The waveform of the interference light is substantially similar to a sinusoidal wave. Since the sinusoidal wave can be approximated in a minute section by a quadratic function, a second-order derivative of the reflected light waveform has a nearly constant value. In other words, it is considered that the underlayer becomes exposed when a variation in the second-order derivative value falls within a predetermined range. It can be ensured that the processing on the to-be-processed layer is stopped at the same time when the underlayer is exposed.

The processing termination detection method can include a difference step of taking a second-order difference of the waveform of the received reflected light after the processing rate is changed, a difference value determination step of determining whether a variation in a value of the second-order difference falls within a predetermined range, and a processing termination step of stopping processing on the to-be-processed layer when it is determined that the variation in the value of the second-order difference falls within the predetermined range.

With the above detection method, after the change of the processing rate, a second-order difference of a waveform of received reflected light is taken. When a variation in second-order derivative value falls within a predetermined range, processing on the to-be-processed layer is stopped. When the to-be-processed layer is completely removed and the film thickness change rate thereof becomes equal to zero, there appears in the reflected light waveform only a waveform of interference light between reflected light from the surface of the mask layer and reflected light from the surface of the to-be-processed layer covered by the mask layer. The waveform of the interference light is substantially similar to a sinusoidal wave. Since the sinusoidal wave can be approximated in a minute section by a quadratic function, the second-order difference of the reflected light waveform has a nearly constant value. In other words, it is considered that the underlayer becomes exposed when the variation in the second-order difference value falls within the predetermined range. It can be ensured that the processing on the to-be-processed layer is stopped at the same time when the underlayer is exposed.

The underlayer can be a silicon oxide layer, the to-be-processed layer can be a single crystal silicon layer, and the process hole can be a through-hole.

With the above detection method, the underlayer is a silicon oxide layer, the to-be-processed layer is a single crystal silicon layer, and the process hole is a through-hole. Thus, in a SOI (silicon-on-insulator) substrate, the processing (etching) on the single crystal silicon layer can reliably be stopped at the same time that the single crystal silicon layer is removed.

The light of long wavelength irradiated onto the substrate can be comprised of red to near-infrared light.

With the above detection method, the light of long wavelength irradiated onto the substrate is comprised of red to near-infrared light. In that case, it is ensured that when the residual film thickness of the single crystal silicon layer decreases to several μms, interfere occurs between the reflected light from the surface of the through hole formation portion of the single crystal silicon layer and the reflected light passing through the single crystal silicon layer and then reflected by the surface of the silicon oxide layer. As a result, it is possible to reliably detect that the residual film thickness of the silicon layer becomes equal to several μms.

The light of long wavelength can have a wavelength thereof falling within a range from 650 nm to 1000 nm.

According to a second aspect of the present invention, there is provided a processing termination detection apparatus for detecting a processing termination point in formation of a process hole in a to-be-processed layer of a substrate comprised of at least an underlayer, the to-be-processed layer, and a mask layer, which are formed in layers in this order, comprising an irradiation section adapted to irradiate light of long wavelength onto the substrate, a light receiving section adapted to receive reflected light from surfaces of at least the to-be-processed layer, the underlayer, and the mask layer of the substrate, a frequency analyzer adapted to perform a frequency analysis of a waveform of the received reflected light, an intensity determination section adapted to determine whether an intensity at a predetermined frequency represented in a result of the frequency analysis exceeds a predetermined threshold value, and a processing rate changeover section adapted to change a processing rate of the to-be-processed layer when it is determined that the intensity at the predetermined frequency exceeds the predetermined threshold value.

With the processing termination detection apparatus of this invention, as in the processing termination detection method of this invention, it is possible to accurately change the etch rate when the residual film thickness of the to-be-processed layer decreases to less than a predetermined value.

The processing termination detection apparatus can include a differentiator adapted to take a second-order derivative of the waveform of the received reflected light after the processing rate is changed, a derivative value determination section adapted to determine whether a variation in a value of the second-order derivative falls within a predetermined range, and a processing termination section adapted to stop processing on the to-be-processed layer when it is determined that the variation in the value of the second-order derivative falls within the predetermined range.

In this case, it is possible to reliably stop the processing on the to-be-processed layer at the same time when the underlayer becomes exposed.

The processing termination detection apparatus can include a difference determinator adapted to take a second-order difference of the waveform of the received reflected light after the processing rate is changed, a difference value determination section adapted to determine whether a variation in a value of the second-order difference falls within a predetermined range, and a processing termination section adapted to stop processing on the to-be-processed layer when it is determined that the variation in the value of the second-order difference falls within the predetermined range.

In this case, it is possible to reliably stop the processing on the to-be-processed layer at the same time when the underlayer becomes exposed.

Further features of the present invention will become apparent from the following description of an exemplary embodiment with reference to the attached drawings.

### BRIEF DESCRIPTION OF THE DRAWINGS

FIG. 1 is a section view schematically showing the construction of a substrate processing apparatus to which is applied a processing termination detection method according to an embodiment of this invention;

FIG. 2 is a section view showing optical path differences between pieces of reflected light from various layers of a wafer;

FIG. 3 is a graph showing observed time-based changes in intensities of pieces of reflected light from a wafer;

FIG. 4 is a graph showing a result of frequency analysis of reflected light in the case of using laser light of a 670 nm wavelength;

FIG. 5 is a graph showing a relation between residual film thickness and the intensity at peak [4] shown in the graph of FIG. 4 in the case of using laser light of a 670 nm wavelength;

FIG. 6 is a flowchart of an etch rate changeover process as a processing termination detection method according to the embodiment;

FIG. 7 is a graph showing an observed time-based change in intensity of reflected light from a wafer;

FIG. 8A is a graph showing a variation in first-order difference value of a reflected light waveform in FIG. 7, the difference value being determined at intervals of 0.1 seconds;

FIG. 8B is a graph showing a second-order difference value;

FIG. 9 is a flowchart of an etching stop process as a processing termination detection method according to the embodiment; and

FIG. 10 is a section view showing notches formed in side surfaces of a through-hole of a wafer.

### DETAILED DESCRIPTION OF THE PREFERRED EMBODIMENT

The present invention will now be described in detail below with reference to the drawings showing a preferred embodiment thereof.

First, an explanation will be given of a substrate processing apparatus to which a processing termination detection method of this embodiment is applied. This substrate processing apparatus is designed to perform plasma etching on a semiconductor wafer W as a substrate (hereinafter simply referred to as the “wafer W”).

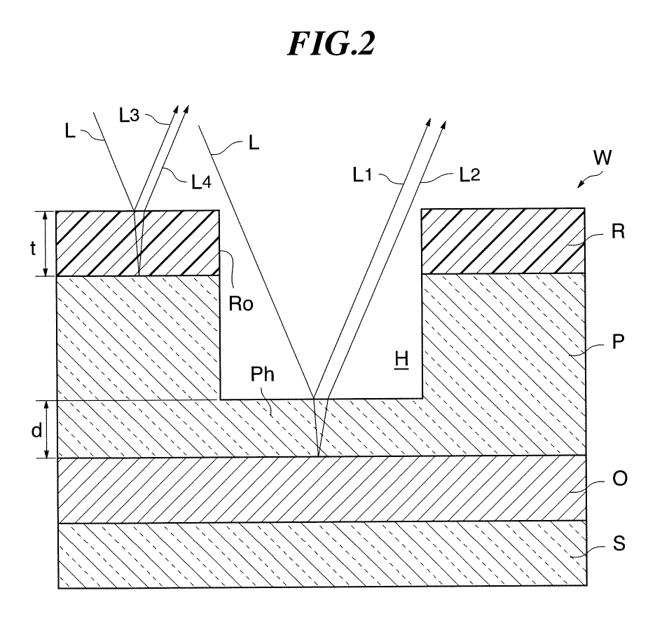

As shown in FIG. 2, which will be explained in detail later, the wafer W includes, as an insulation layer, a silicon oxide layer O (underlayer) between a single crystal silicon layer S and a single crystal silicon layer P (a to-be-processed layer) and includes a resist layer R (mask layer) formed on the silicon layer P and formed with an opening portion Ro in a predetermined pattern.

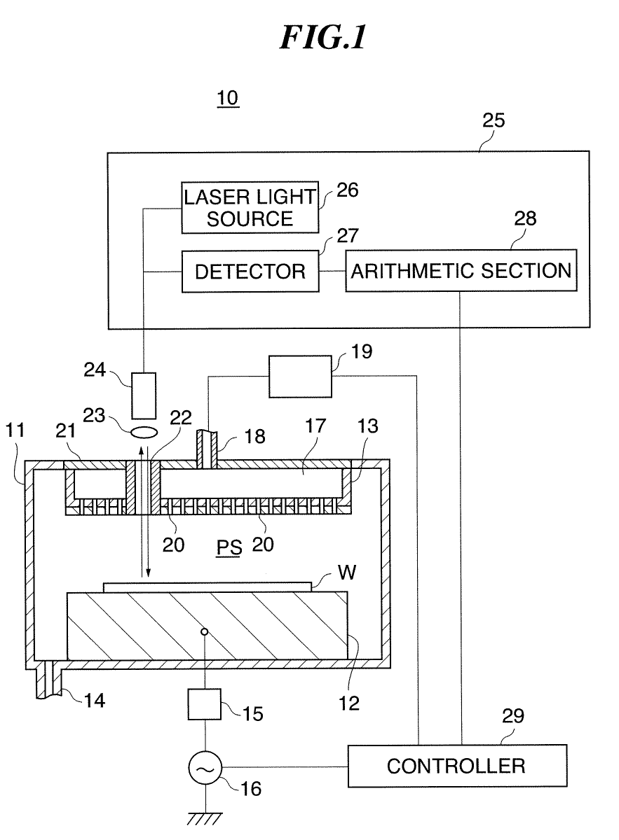

FIG. 1 is a section view schematically showing the construction of a substrate processing apparatus to which is applied a processing termination detection method of this embodiment.

Referring to FIG. 1, the substrate processing apparatus 10 includes a processing chamber 11 made of a conductive material such as aluminum, a lower electrode 12 disposed on a bottom surface of the processing chamber 11 and serving as a mounting stage for mounting thereon a semiconductor wafer W, and a shower head 13 disposed above the lower electrode 12 with a predetermined distance therefrom.

The processing chamber 11 has a lower part thereof formed with an exhaust unit 14 to which a vacuum exhausting unit (not shown) is connected, and the lower electrode 12 is connected with a high-frequency power supply 16 via a matcher 15. A buffer chamber 17 disposed in the shower head 13 is connected with a processing gas introduction pipe 18 to which a processing gas supply unit 19 is connected. The shower head 13 is formed at its lower part with a plurality of gas holes 20 through which the buffer chamber 17 is communicated with a processing space PS defined between the shower head 13 and the lower electrode 12. The shower head 13 is supplied at its buffer chamber 17 with processing gas from the processing gas introduction pipe 18 and supplies the processing gas through the gas holes 20 to the processing space PS.

In the substrate processing apparatus 10, the inside of the processing chamber 11 is depressurized by the exhaust unit 14 to a predetermined vacuum, and then the processing gas is supplied from the shower head 13 to the processing space PS, with high frequency power supplied to the lower electrode 12, whereby a plasma of the processing gas is generated in the processing space PS. The generated plasma is supplied to a wafer W via the opening portion Ro of the resist layer R and collides and contacts the single crystal silicon layer P. As a result, the silicon layer P is etched and formed with a through-hole.

A monitor unit 21 for monitoring from above the wafer W placed on the lower electrode 12 is disposed in the shower head 13 in the processing chamber 11. The monitor unit 21 is made of a cylindrical member and disposed to extend through the shower head 13. The monitor unit 21 has an upper end thereof provided with a window member 22 made of a transparent material such as quartz glass. An optical fiber 24 is disposed above the processing chamber 11 so as to face the upper end of the monitor unit 21 with a condenser lens 23 therebetween.

The optical fiber 24 is connected to a termination detection unit 25 (a processing termination detection apparatus) for detecting a termination point in the etching process on the single crystal silicon layer P. The termination detection unit 25 includes a laser light source 26 (an irradiation section) and an arithmetic section 28 (a frequency analyzer, a differentiator, and a difference determinator) connected to a detector 27 (a light receiving section), the laser light source and the arithmetic section being connected to the optical fiber 24. The termination detection unit 25 operates under the control of a controller 29 of the substrate processing apparatus 10. For example, a semiconductor laser is used as a laser light source 26, and a hotomultiplier or a photo diode is employed as the detector 27. The controller 29 controls various parts of the substrate processing apparatus 10.

The termination detection unit 25 irradiates laser light from the laser light source 26 onto the wafer W on the lower electrode 12 through the optical fiber 24, the condenser lens 23, and the monitor unit 21, and receives reflected light from the wafer W by the detector 27 through the optical fiber 24 and the like. The reflected light received by the detector 27 is converted into an electric signal and transmitted to the arithmetic section 28. Based on the received electric signal, the arithmetic section 28 performs frequency analysis of a waveform of the reflected light, as described later, and performs second-order differentiation on the waveform or determines second-order difference of the waveform.

Next, with reference to FIG. 2, a relation between the residual film thickness of the single crystal silicon layer P and the reflected light will be described. FIG. 2 is a section view showing optical path differences between pieces of reflected light from various layers of the wafer.

Referring to FIG. 2, the single crystal silicon layer P exposed through the opening portion Ro of the resist layer R is being etched for formation of a through-hole H. To this end, laser light L is irradiated toward a through-hole formation portion Ph of the silicon layer P. Part of the irradiated laser light L is reflected by a surface of the through-hole formation portion Ph of the silicon layer P having a residual film thickness of d, whereas the remaining part of the laser light L passes through the silicon layer P and is then reflected by a surface of the silicon oxide layer O. As shown in FIG. 2, there is an optical path difference (of about 2d) between the reflected light L1 from the surface of the silicon layer P and the reflected light L2 from the surface of the silicon oxide layer O. The optical path difference corresponds to a phase difference between these two pieces of reflected light. The two pieces of reflected light (L1, L2) produce interference light (hereinafter referred to as the “residual layer interference light”).

The residual layer interference light has the smallest amplitude (the lowest intensity) when the just-mentioned optical path difference is an integral multiple of the wavelength of the light passing through the silicon layer P, i.e., when there is a relation of 2d=mλ1. On the other hand, the residual layer interference light has the largest amplitude (the highest intensity) when the optical path difference is shifted by the half-wave length from the above described optical path difference, i.e., when there is a relation of 2d=mλ1+λ1/2, where λ1 represents the wavelength of the light passing through the silicon layer P, and m represents an arbitrary integer.

Assuming that the wavelength of the reflected light observed in the air is λ0 and the refractive index of the single crystal silicon layer P is n, there is a relation of λ1=λ0/n between n, λ0, and λ1. Based on this relation, the residual film thicknesses d at which the residual layer interference light has the lowest and highest intensities, respectively, can be determined as shown by the following formulae (1) and (2).

d=(mλ0/2n) (1)

d=mλ0/2n+λ0/4n (2)

The residual film thickness d decreases with elapse of time by being etched, and therefore, the optical path difference decreases with elapse of time. Since formulae (1) and (2) are periodically satisfied with the decrease in the residual film thickness d, the intensity of the residual layer interference light periodically varies between a local maximum value and a local minimum value thereof with the decrease in the residual film thickness d.

In the case of formation of a through-hole H having a small aperture rate, laser light L is irradiated to not only inside the through-hole H but also the vicinity of the through-hole H. Part of the laser light L irradiated to the vicinity of the through-hole H is reflected by a surface of the resist layer R, whereas the remaining part of the laser light L passes through the resist layer R and is reflected by a surface of the single crystal silicon layer P covered by the resist layer R (hereinafter referred to as the “covered silicon layer P”). Between the reflected light L3 from the surface of the resist layer R and the reflected light L4 from the surface of the covered silicon layer P, there is an optical path difference of about 2t, where t represents the thickness of the resist layer R, as shown in FIG. 2, and these two pieces of reflected light (L3, L4) produce interference light (hereinafter referred to as the “mask layer interference light”). Furthermore, there is an optical path difference between the reflected light L1 from the surface of the silicon layer P and the reflected light L4 from the surface of the covered silicon layer P, and these two pieces of reflected light (L1, L4) produce interference light (hereinafter referred to as the “through-hole interference light”). The detector 27 receives not only the residual layer interference light but also the mask layer interference light and the through-hole interference light. Thus, the residual layer interference light, the mask layer interference light, and the through-hole interference light are superimposed on reflected light received by the detector 27.

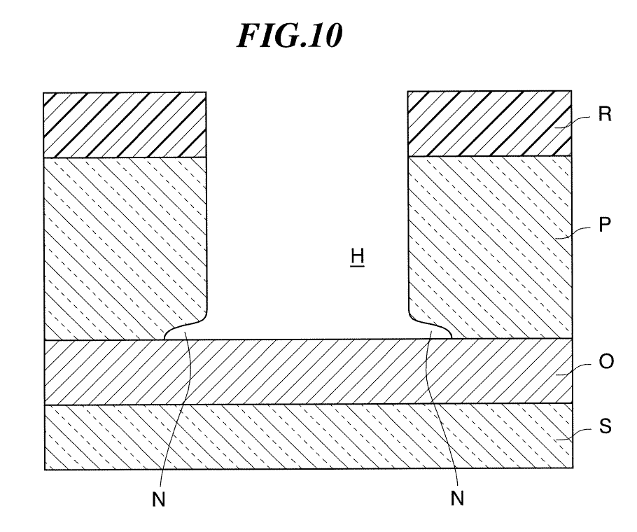

In order to prevent the formation of notches N shown in FIG. 10, the etch rate must be changed when the residual film thickness d of the through-hole formation portion Ph of the silicon layer P has become smaller than a predetermined thickness. In general, the single crystal silicon layer P hardly permits laser light to pass therethrough. Thus, the above described reflected light L2 is produced only after the residual film thickness d of the single crystal silicon layer P becomes small. In other words, the residual layer interference light is produced only after the residual film thickness d of the silicon layer P becomes small. This indicates that it is reasonable to determine that the residual film thickness d of the through-hole formation portion Ph of the single crystal silicon layer P becomes smaller than a predetermined value when the intensity of the residual layer interference light has increased to a certain magnitude. However, since the mask layer interference light and the through-hole interference light as well as the residual layer interference light are superimposed on reflected light from the wafer W, it is difficult to observe only the residual layer interference light.

In order to grasp the substance of various pieces of interference light, the present inventors carried out the etching of a single crystal silicon layer P of a wafer W using the substrate processing apparatus 10, in which three types of laser light L having different wavelengths (410 nm, 670 nm, and 780 nm) were irradiated in this order onto the wafer W from the laser light source 26 of the termination detection unit 25, and pieces of reflected light from the wafer W were each received by the detector 27. Then, the present inventors observed time-based changes in intensities of the pieces of reflected light (interference waveforms). The thicknesses of the silicon layer P, the silicon oxide layer O, and the resist layer R of the wafer W measured before etching were 200 μm, 2 μm, and 4 μm, respectively. The etch rate of the silicon layer P was set to 20 μm/min, and the selection ratio of the single crystal silicon layer P to the resist layer R was set to 20. The through-hole H had an aperture rate of 50%.

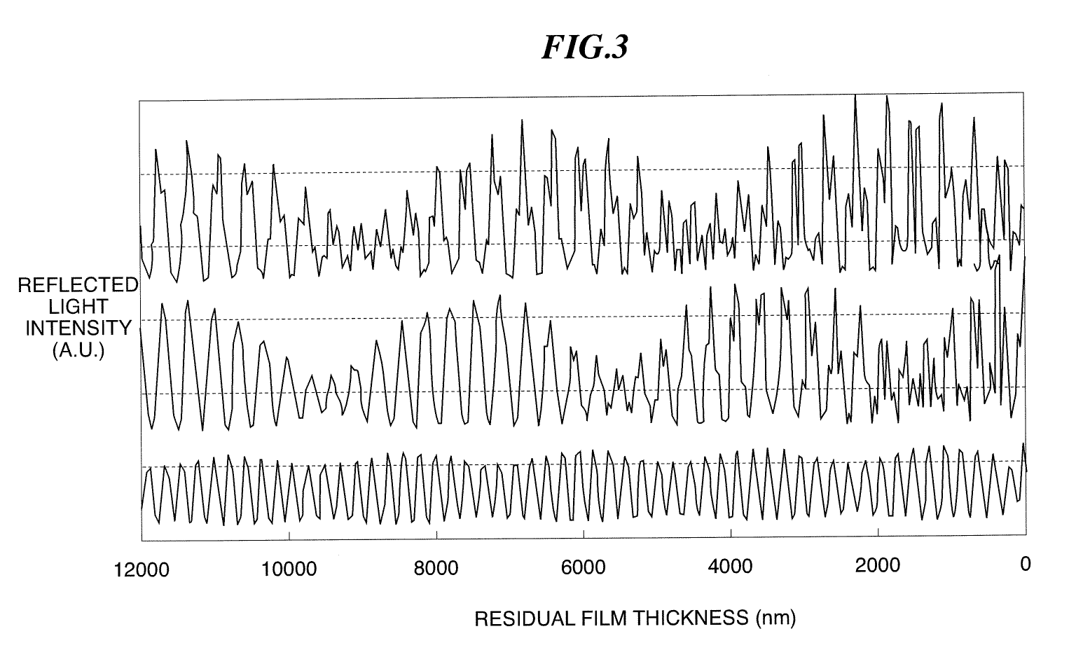

FIG. 3 is a graph showing observed time-based changes in reflected light intensities. In FIG. 3, the residual film thickness d of the single crystal silicon layer P is taken along the abscissa, whereas the reflected light intensity is taken along the ordinate. Values along the ordinate are represented in arbitrary unit. Reflected light waveforms shown in a lower part, a middle part and an upper part of FIG. 3 were each observed when laser light L of a wavelength of 410 nm, 670 nm, or 780 nm was irradiated. Any and each of these waveforms is disordered, from which it is understood that each reflected light waveform is comprised of a plurality of waveforms superimposed on one another.

In particular, it is understood that the reflected light waveforms each observed when the laser light L of a 670 nm wavelength or a 780 nm wavelength was irradiated are largely disordered in the range of the residual film thickness d of the silicon layer P equal to or less than 4 μm (4000 nm) and in the range equal to or less than 8 μm (8000 nm), respectively. It is considered that this is because, in addition to the mask layer interference light and the through-hole interference light, the residual layer interference light was superimposed on the reflected light.

The reason why the residual layer interference light was superimposed on the reflected light from a midpoint in the film thickness range in FIG. 3 is that the reflected light L2 was produced only after the residual film thickness d of the silicon layer P had decreased to some small value. The reason why the superimposition of the residual layer interference light on the reflected light in the case of using the laser light L of a 780 nm wavelength started at a larger film thickness than in the case of using the laser light L of a 670 nm wavelength is that polysilicon generally has a smaller light absorption coefficient for the light passing therethrough of longer wavelength, so that the generation of the reflected light L2 in the case of laser light of a 780 nm wavelength may be started at a larger residual layer film thickness than in the case of the laser light of a 670 nm wavelength.

On the other hand, the frequency of each of the residual layer interference light, the mask layer interference light, and the through-hole interference light is determined by a rate of change in optical path difference. The rate of change in optical path difference is determined by a film thickness change rate (a thickness reduction rate) in the layer concerned, a rate of change in depth of the through-hole, and the refractive index of the layer. Since the etch rate of the resist layer R is normally different from that of the single crystal silicon layer P, the film thickness reduction rate of the resist layer R differs from that of the through-hole formation portion Ph of the silicon layer P. Furthermore, the refractive index of the resist layer R differs from that of the silicon layer P. Thus, the frequencies of the residual layer interference light, the mask layer interference light, and the through-hole interference light are different from one another. Each reflected light waveform shown in the graph of FIG. 3 indicates the presence of pieces of interference light having different frequencies. Thus, it is verified that the residual layer interference light, the mask layer interference light, and the through-hole interference light have different frequencies from one another.

In the processing termination detection method of this embodiment, the residual layer interference light is observed, which is selected from reflected light on which pieces of interference light are superimposed, utilizing the fact that the residual layer interference light, the mask layer interference light and, the through-hole interference light have different frequencies. More specifically, a frequency analysis (for example, FFT (fast Fourier transformation) or MEM (maximum entropy method)) is carried out on the reflected light. This makes it possible to calculate the intensities of the reflected light at various frequencies. In particular, the intensity of the reflected light at a frequency corresponding to the residual layer interference light is observed, whereby the residual layer interference light can be monitored separately from the mask layer interference light and the through-hole interference light.

In the processing termination detection method of this embodiment, the frequency analysis of the reflected light is repeatedly carried out to calculate the intensities of the reflected light at various frequencies and monitor the intensity of the reflected light at a frequency corresponding to the residual layer interference light. When the intensity at the frequency corresponding to the residual layer interference light exceeds a predetermined threshold value, it is determined that the residual film thickness d of the single crystal silicon layer P becomes less than a predetermined value.

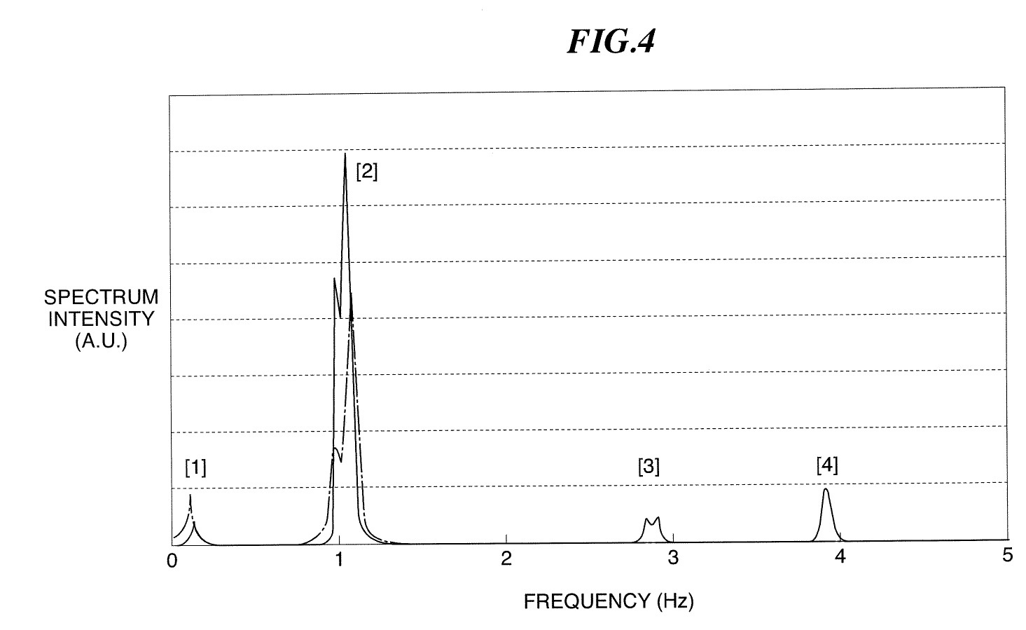

FIG. 4 is a graph showing a result of the frequency analysis of reflected light (spectrum intensity distribution) in the case of using laser light of a 670 nm wavelength. In FIG. 4, the frequency is taken along the abscissa, and the spectrum intensity is taken along the ordinate. Values along the ordinate are shown in arbitrary unit. A one-dotted chain line represents a case where the residual film thickness d of the silicon layer P is large, whereas a fine solid line represents a case where the residual film thickness d is small. Furthermore, the intensity of the mask layer interference light is represented by a peak at [1], the intensity of the through-hole interference light is represented by a peak at [2], the intensity of interference light between the reflected light L2 from the surface of the silicon oxide layer O and reflected light L3 from the surface of the resist layer R is represented at [3], and the intensity of the residual layer interference light is represented at [4].

It is understood from the graph of FIG. 4 that the frequency analysis of the reflected light from the wafer W makes it possible to clearly separate the residual layer interference light from the mask layer interference light and the through-hole interference light and monitor the separated residual layer interference light. The reason why the peaks [3], [4] were observed only at small residual film thicknesses d of the silicon layer P is that the reflected light L2 was produced only after the residual film thickness d of the silicon layer P had decreased to some small value.

Furthermore, it is understood that each peak did not appear at only one frequency but appeared in a frequency band of some width, as shown in the graph of FIG. 4. Thus, to monitor the residual layer interference light, it is not sufficient to observe the reflected light intensity at only one frequency. Preferably, the intensity should be observed in a frequency band of some width.

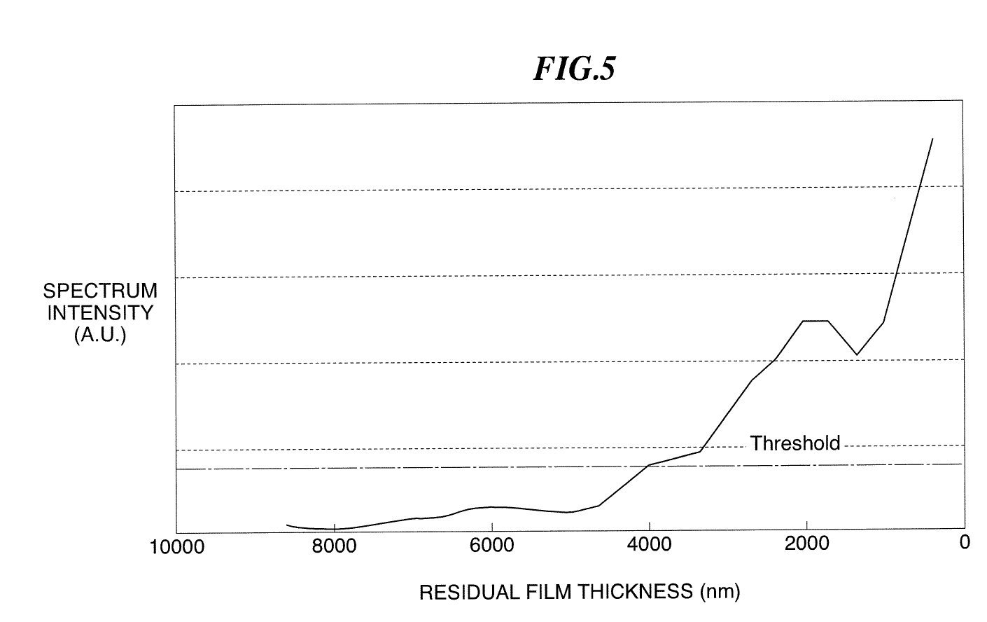

FIG. 5 is a graph showing a relation between the residual film thickness and the intensity at peak [4] in the graph of FIG. 4 in the case of using laser light of a 670 nm wavelength. In FIG. 5, the residual film thickness is taken along the abscissa and the spectrum intensity is taken along the ordinate. Values along the ordinate are shown in arbitrary unit.

As shown in FIG. 5, the reflected light intensity at the peak [4] increases with the decrease in the residual film thickness d of the silicon layer P. It is confirmed that a predetermined threshold value (denoted by a legend “Threshold” in FIG. 5) is exceeded when the residual film thickness d becomes less than 4 μm (4000 nm). In other words, it is understood that the frequency analysis of reflected light in the case of using laser light L of a 670 nm wavelength makes it possible to determine whether or not the residual film thickness d of the through-hole formation portion Ph of the silicon layer P decreases to less than 4 μm (4000 nm).

Next, an explanation will be given of an etch rate changeover process as a processing termination detection method of this embodiment. This process is performed by the termination detection unit 25 or the controller 29 in order to change the etch rate to prevent notches N from being formed after the residual film thickness d of the through-hole formation portion Ph of the single crystal silicon layer P has decreased to a predetermined value.

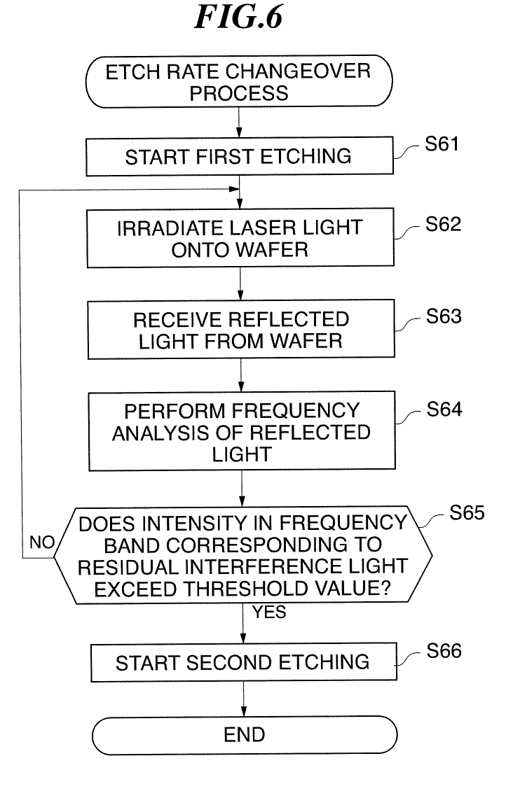

FIG. 6 is a flowchart of the etch rate changeover process of the processing termination detection method of this embodiment.

Referring to FIG. 6, a wafer W is first placed on the lower electrode 12 of the substrate processing apparatus 10. Then, first etching is started for formation of a through-hole H corresponding to an opening portion Ro of a resist layer R (step S61). In the first etching, the selection ratio of the single crystal silicon layer P to the resist layer R is set to 20, and the silicon layer P is rapidly etched.

Then, in the termination detection unit 25, laser light L comprised of red to near-infrared light is irradiated from the laser light source 26 onto the wafer W (step S62) (irradiation step), reflected light from the wafer W is received by the detector 27 (step S63) (light reception step), and the received reflected light is converted into an electric signal that is then transmitted to the arithmetic section 28 of the unit 25. It is preferable that the period (=1/frequency) of sampling the reflected light in the step S63 be set to be equal to or larger than 50 Hz.

Based on the received electric signal, the arithmetic section 28 performs a frequency analysis of the reflected light waveform using FFT or the like (step S64) (frequency analysis step). The controller 29 observes reflected light intensities in frequency bands respectively corresponding to pieces of interference light superimposed on the reflected light, referring to a result of the frequency analysis.

Next, the controller 29 determines whether or not the intensity in the frequency band (around a predetermined frequency) corresponding to residual layer interference light (the intensity at peak [4] in FIG. 4) exceeds a predetermined threshold value (step S65) (intensity determination step).

If the result of determination in the step S65 indicates that the intensity in the frequency band corresponding to the residual layer interference light does not exceed the threshold value, the process returns to the step S62. On the other hand, if the intensity in that frequency band exceeds the threshold value, second etching is started that removes the through-hole formation portion Ph of the single crystal silicon layer P to cause the silicon oxide layer O to be exposed (step S66) (processing rate changeover step), whereupon the present process is completed.

As shown in the graph of FIG. 3, in the case of using 780 nm wavelength laser light L, residual layer interference light is newly superimposed on the reflected light when the residual film thickness d of the silicon layer P has become equal to or less than 8 μm (8000 nm). In the case of 670 nm wavelength laser light, residual layer interference light is newly superimposed when the residual film thickness d of the silicon layer P has become equal to or less than 4 μm (4000 nm). Thus, in the case of using the 780 nm wavelength laser light L, it is preferable that the intensity of the residual layer interference light be measured in advance at a 8 μm residual film thickness d of the silicon layer P, and the measured intensity be set as the threshold value in the step S65. In the case of using of 670 nm wavelength laser light, it is preferable that the intensity of the residual layer interference light at a 4 μm residual film thickness d be measured in advance and the measured intensity be set as the threshold value in the step S65.

The etch rate of the single crystal silicon layer P in the second etching is different from that in the first etching, and the selection ratio of the single crystal silicon layer P to the silicon oxide layer O is set to a large value, to thereby prevent the silicon oxide layer O from being etched.

In the process shown in FIG. 6, after start of the first etching, reflected light from the wafer W irradiated with laser light L is received, and a frequency analysis of a waveform of the received reflected light is carried out. From the result of the frequency analysis, if it is determined that the reflected light intensity in a frequency band corresponding to the residual layer interference light exceeds the threshold value, the second etching is started. In other words, the etch rate of the single crystal silicon layer P is changed.

Due to interferences between pieces of reflected light from surfaces of various layers of the wafer W, there are produced pieces of interference light (for example, residual layer interference light, mask layer interference light, and through-hole interference light). With advancement of the etching and with elapse of time, there occur changes in the film thicknesses of the single crystal silicon layer P and the resist layer R, which results in changes in optical path lengths of pieces of reflected light that passing through the respective layers of the wafer. Hence, the intensity of each interference light periodically changes. Furthermore, since the film thickness change rate of the single crystal silicon layer P differs from that of the resist layer R, the period (frequency) of change in intensity is different between pieces of interference light. In other words, pieces of interference light having different frequencies are superimposed on the reflected light. Thus, the frequency analysis of the reflected light waveform makes it possible to monitor the residual layer interference light separately from the mask layer interference light and the through-hole interference light. Thus, a shift from the first etching to the second etching can be made in time with the residual film thickness d of the silicon layer P having decreased to less than the predetermined value.

In the process shown in FIG. 6, there is used laser light L comprised of red to near-infrared light. Since polysilicon has a smaller light absorption coefficient for light transmitting therethrough of a longer wavelength. In the case of using laser light L comprised of red to near-infrared light, reflected light L2 passing through the single crystal silicon layer P and reflected by a surface of the silicon oxide layer O is produced after the residual film thickness d of the single crystal silicon layer P has decreased to some magnitude. Therefore, from an early stage, interference is produced between the reflected light L2 and the reflected light L1 from the surface of the through-hole formation portion Ph of the single crystal silicon layer P. Specifically, in the case of using laser light L whose wavelength falls within a range from 650 nm to 1000 nm, the above described interference is produced when the residual film thickness d of the silicon layer P has decreased to a value falling in the range from 4 to 8 μm. Thus, it is possible to reliably detect when the residual film thickness d has a value in the range from 4 to 8 μm.

In the process in FIG. 6, the period of sampling the reflected light is set to be equal to or higher than 50 Hz. The present inventors confirmed that the period of change in the residual layer interference light intensity fallen within the rage from 0.105 to 0.127 seconds in the case where the etch rate of the single crystal silicon layer P was set to 50 μm/min, the selection ratio of the silicon layer P to the resist layer R in the etching was set to 20, and the wavelength of laser light L was set to have a value falling within the wavelength range of red to near-infrared light. Thus, using the sampling period higher than 50 Hz, data of 5 points or more can be sampled within one period of intensity change (interference), which makes it possible to implement an accurate frequency analysis of the waveform of the received reflected light.

In the above described process shown in FIG. 6, the reflected light intensity in a frequency band corresponding to the residual layer interference light is observed using the frequency analysis. However, there may be observed the reflected light intensity in a frequency band (the intensity appearing at peak [3] in FIG. 4) corresponding to interference light between reflected light L2 from the surface of the silicon oxide layer O and reflected light L3 from the surface of the resist layer R, and the second etching may be started when the intensity in that frequency band exceeds a predetermined threshold value.

In processing a through-hole having a large aperture rate, there occurs a change in a plasma emission state observed above the through-hole when the single crystal silicon layer P is removed so that the silicon oxide layer O is exposed, the to-be-etched layer is changed from the silicon layer to the silicon oxide layer. By detecting a change in emission state using a spectroanalysis, it is possible to detect when the silicon oxide layer O has been exposed.

However, a through-hole H for use in three-dimension mounting has a small aperture rate. In that case, even when the silicon oxide layer O is etched to some extent, the plasma emission state above the through-hole H does not change, making it difficult to detect by means of plasma spectroanalysis that the silicon oxide layer O has been exposed. In view of this, the processing termination detection method according to this embodiment detects that the silicon oxide layer O has been exposed using the above described reflected light.

When the silicon oxide layer O is exposed by the second etching, the residual film thickness d of the through-hole formation portion Ph of the single crystal silicon layer P becomes zero. Thereafter, the residual film thickness no longer changes. As a result, the intensities of pieces of interference light, such as for example, the residual layer interference light and the through-hole interference light, are stopped from varying, and hence only the waveform of the mask layer interference light appears in the waveform of the reflected light received by the detector 27.

In order to gasp the substance of stoppage of a variation in the intensities of the residual layer interference light and the through-hole interference light, the present inventors observed a time-based change in reflected light intensity during the second etching in which laser light L of 670 nm wavelength was irradiated onto a wafer W from the laser light source 26 of the termination detection unit 25 and reflected light from the wafer W was received by the detector 27. The silicon oxide layer O in the wafer W had a thickness of 2 μm, the single crystal silicon layer P was etched at an etch rate of 20 μm/min, with the selection ratio of the silicon layer P to the resist layer R in the etching being set to 20 and with the aperture rate of the through-hole H being 10%.

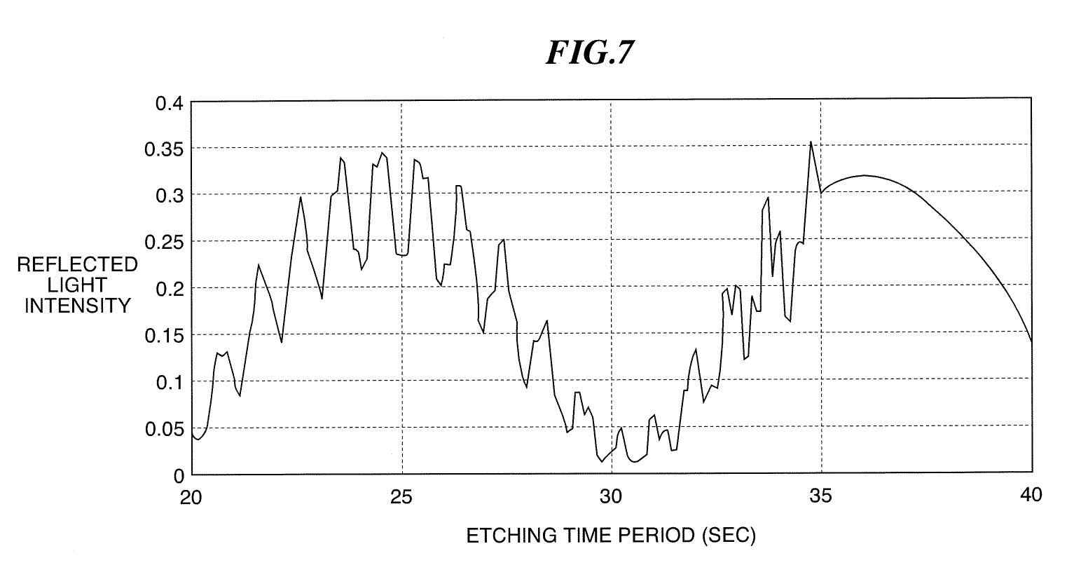

FIG. 7 is a graph showing an observed time-based change in the intensity of reflected light from a wafer. In FIG. 7, the etching time period is taken along the abscissa, and the reflected light intensity (reflection intensity) is taken along the ordinate.

It was confirmed that in a state where the single crystal silicon layer P remained (before elapse of 35 seconds from the start of etching), the reflection light waveform was disordered. On the other hand, after the single crystal silicon layer P had been removed and the silicon oxide layer O was exposed (after elapse of 35 seconds), the reflected light waveform was not disordered and there appeared only a waveforms of a large period. During the etching of the silicon layer P, the etch rate of the resist layer R is normally small, and the film thickness change rate of the resist layer R is small. Thus, the intensity of the mask layer interference light changes with a long period. It is therefore considered that the reflected light waveform observed after exposure of the silicon oxide layer O corresponds to a waveform of the mask layer interference light. The graph shown in FIG. 7 indicates that only the waveform of the mask layer interference light appeared in the reflected light waveform after the exposure of the silicon oxide layer O.

As shown in the graph of FIG. 7, the reflected light waveform observed after the exposure of the silicon oxide layer O is substantially similar to a sinusoidal wave, so that in a minute section the waveform can be approximated to a quadratic function. Thus, if the reflected light waveform observed after the exposure of the silicon oxide layer O is subjected to a second-order differentiation or a second-order difference determination, then a second-order derivative value or a second-order difference value of the reflected light waveform is nearly constant and a variation in the second-order derivative value or in the second-order difference value falls within a predetermined range.

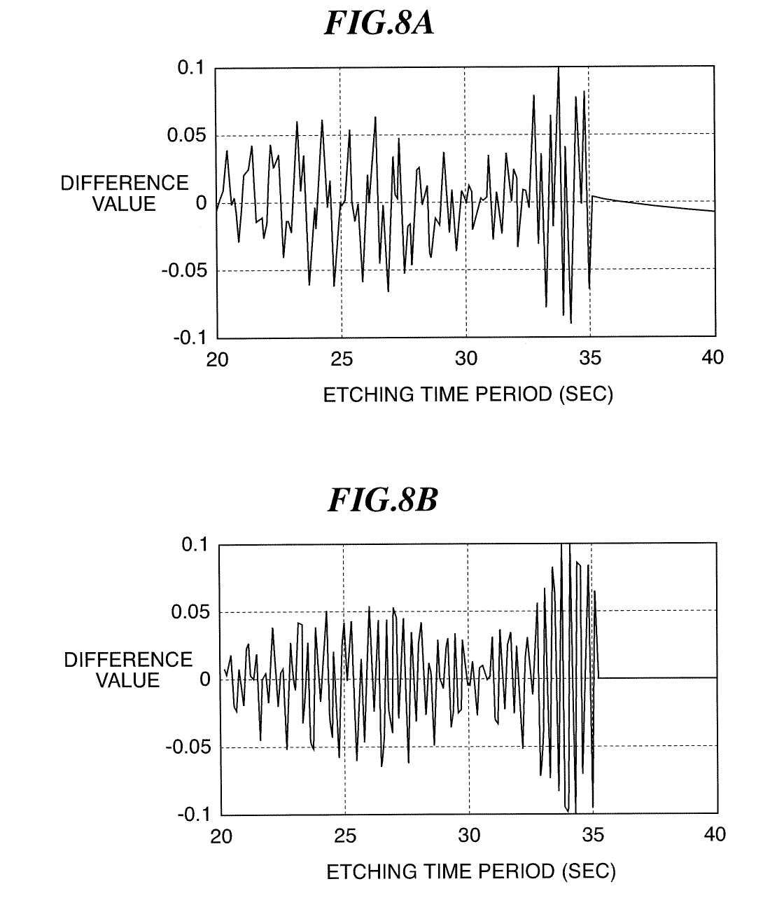

FIG. 8A is a graph showing a variation in a first-order difference value of the reflected light waveform shown in FIG. 7, the difference value being determined at intervals of 0.1 seconds, and FIG. 8B shows a second-order difference value.

In FIGS. 8A and 8B, the etching time period is taken along the abscissa, and the difference value is taken along the ordinate.

From the graph in FIG. 5B, it is confirmed that the second-order difference value is nearly constant (a value of zero) and a variation in the second-order difference value is also nearly constant (a value of zero) after exposure of the silicon oxide layer O (after elapse of 35 seconds). In other words, the graphs shown in FIGS. 8A and 8B indicate that after the exposure of the silicon oxide layer O a variation in the second-order difference value (or the second-order derivative value) of the reflected light waveform obtained by the second-order difference determination (or the second-order differentiation) falls within a predetermined range.

In the following, an etch rate changeover process as a processing termination detection method according to this embodiment will be explained. This process is implemented by the termination detection unit 25 or the controller 29, when the second etching is started for the through-hole formation portion Ph of the single crystal silicon layer P.

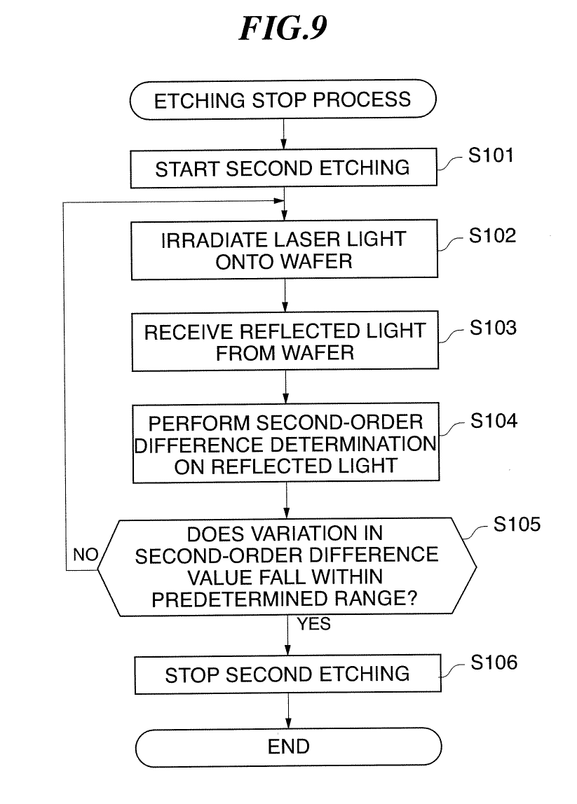

FIG. 9 is a flowchart of an etching stop process as a processing termination detection method according to this embodiment.

Referring to FIG. 9, the second etching in the step S66 in FIG. 6 on the through-hole formation portion Ph of the single crystal silicon layer P is started (step S101). In the termination detection unit 25, the laser light source 26 irradiates laser light L comprised of red to near-infrared light onto a wafer W (step S102). The detector 27 receives the reflected light from the wafer W (step S103) and converts the received reflected light into an electric signal, which is transmitted to the arithmetic section 28 of the termination detection unit 25.

Based on the received electric signal, the arithmetic section 28 performs a second-order difference determination (or a second-order differentiation) on the reflected light waveform (step S104) (difference determination step or differentiation step). The controller 29 determines whether or not a variation in the second-order difference value (or in the second-order derivative value) falls within a predetermined range (step S105) (derivative or difference value determination step).

If the result of the determination in the step S105 indicates that a variation in the second-order difference value (or in the second-order derivative value) falls out of the predetermined range, the process returns to the step S102. On the other hand, if it is determined that the variation in the second-order difference value (or in the second-order derivative value) falls within the predetermined range, then it is determined that the silicon oxide layer O has been exposed and the second etching is stopped (step S106) (processing stop step), whereupon the present process is completed.

With the process shown in FIG. 9, the waveform of the reflected light received after the start of the second etching is subjected to the second-order difference determination (or the second-order differentiation), and if a variation in the second-order difference value (or in the second-order derivative value) falls within a predetermined range, the second etching is stopped.

When the single crystal silicon layer P is completely removed and a film thickness change rate of the silicon layer P becomes zero, only a waveform of the mask layer interference light appears in the reflected light waveform. The waveform of the mask layer interference light is substantially similar to a sinusoidal wave. Since in a minute section a sinusoidal wave can be approximated by a quadratic function, a second-order difference value (or a second-order derivative value) of the reflected light waveform obtained by subjecting the waveform to a second-order difference determination (or a second-order differentiation) is nearly constant. In other word, if a variation in the second-order difference value (or in the second-order derivative value) becomes within in a predetermined range, it is considered that the silicon oxide layer O has been exposed. Thus, it is possible to stop the second etching simultaneously when the silicon oxide layer O becomes exposed, making it possible to prevent notches N from being formed.

The present inventors performed etching using laser light L of a 670 nm wavelength, in which the etch rate of the single crystal silicon layer P was set to 20 μm/min, and the selection ratio of the silicon layer P to the resist layer R in the etching was set to 20. In addition, the second-order difference determination was performed on the reflected light waveform at intervals of 0.1 seconds, 0.3 seconds, 0.5 seconds, and 1.0 second, respectively. The present inventors confirmed that in a case where the second-order difference determination was carried out at intervals of 0.5 seconds, there occurred a largest variation in the second-order difference value before exposure of the silicon oxide layer O. The period of change in intensity of the residual layer interference light at that time was about 1.0 second. From the above, it is understood that a change in variation in the second-order difference value can reliably be determined by setting the interval of the second-order difference determination on the reflected light waveform to about one-half of the period of a change in the intensity of the residual layer interference light.

A through-hole H having an excessively small aperture rate makes it difficult to receive the reflected light L1 from the surface of the through-hole formation portion Ph of the single crystal silicon layer P. Thus, it is preferable that the aperture rate of the through-hole H be at least 10%. Specifically, in the case of the through-hole H having a diameter thereof varying in the range from 30 to 60 μm, it is preferable that a spot diameter which represents a range of irradiation of laser light L be set in the range from 70 to 100 μm.

It is to be understood that the present invention may also be accomplished by supplying a computer (controller 29, for example) with a storage medium in which a program code of software, which realizes the functions of the above described embodiment, is stored, and causing the computer to read out and execute the program code stored in the storage medium.

In this case, the program code itself read from the storage medium realizes the functions of the above described embodiment, and therefore the program code and the storage medium in which the program code is stored constitute the present invention.

Examples of the storage medium for supplying the program code include a RAM, an NV-RAM, a floppy (registered trademark) disk, a hard disk, a magnetic-optical disk, an optical disk such as a CD-ROM, a CD-R, a CD-RW, a DVD-ROM, a DVD-RAM, a DVD-RW, a DVD+RW, a magnetic tape, a nonvolatile memory card, and a ROM. Alternatively, the program may be downloaded from another computer, a database, or the like, not shown, connected to the Internet, a commercial network, a local area network, or the like.

Further, it is to be understood that the functions of the above described embodiment may be accomplished not only by executing the program code read out by a computer, but also by causing an OS (operating system) or the like which operates on the computer to perform a part or all of the actual operations based on instructions of the program code.

Further, it is to be understood that the functions of the above described embodiment may be accomplished by writing a program code read out from the storage medium into a memory provided on an expansion board inserted into a computer or a memory provided in an expansion unit connected to the computer and then causing a CPU or the like provided in the expansion board or the expansion unit to perform a part or all of the actual operations based on instructions of the program code.

The program code may be in any of the forms of an object code, a program code executed by an interpreter, script data supplied to an OS (Operating System), etc.

What is claimed is:

1. A processing termination detection method for use in forming a process hole in a to-be-processed layer of a substrate comprised of at least an underlayer, the to-be-processed layer, and a mask layer, which are formed in layers in this order, comprising:
an irradiation step of irradiating light of long wavelength onto the substrate;
a light reception step of receiving reflected light from surfaces of at least the to-be-processed layer, the underlayer, and the mask layer of the substrate;
a frequency analysis step of performing a frequency analysis of a waveform of received reflected light;
an intensity determination step of determining whether an intensity at a predetermined frequency represented in a result of the frequency analysis exceeds a predetermined threshold value; and
a processing rate changeover step of changing a processing rate of the to-be-processed layer when it is determined that the intensity at the predetermined frequency exceeds the predetermined threshold value.

2. The processing termination detection method according to claim 1, including:
a differentiation step of taking a second-order derivative of the waveform of the received reflected light after the processing rate is changed;
a derivative value determination step of determining whether a variation in a value of the second-order derivative falls within a predetermined range; and
a processing termination step of stopping processing on the to-be-processed layer when it is determined that the variation in the value of the second-order derivative falls within the predetermined range.

3. The processing termination detection method according to claim 1, including:
a difference step of taking a second-order difference of the waveform of the received reflected light after the processing rate is changed;
a difference value determination step of determining whether a variation in a value of the second-order difference falls within a predetermined range; and
a processing termination step of stopping processing on the to-be-processed layer when it is determined that the variation in the value of the second-order difference falls within the predetermined range.

4. The processing termination detection method according to claim 1, wherein the underlayer is a silicon oxide layer, the to-be-processed layer is a single crystal silicon layer, and the process hole is a through-hole.

5. The processing termination detection method according to claim 4, wherein the light of long wavelength irradiated onto the substrate is comprised of red to near-infrared light.

6. The processing termination detection method according to claim 5, wherein the light of long wavelength has a wavelength thereof falling within a range from 650 nm to 1000 nm.

7. A processing termination detection apparatus for detecting a processing termination point in formation of a process hole in a to-be-processed layer of a substrate comprised of at least an underlayer, the to-be-processed layer, and a mask layer, which are formed in layers in this order, comprising:
an irradiation section adapted to irradiate light of long wavelength onto the substrate;
a light receiving section adapted to receive reflected light from surfaces of at least the to-be-processed layer, the underlayer, and the mask layer of the substrate;
a frequency analyzer adapted to perform a frequency analysis of a waveform of the received reflected light;
an intensity determination section adapted to determine whether an intensity at a predetermined frequency represented in a result of the frequency analysis exceeds a predetermined threshold value; and
a processing rate changeover section adapted to change a processing rate of the to-be-processed layer when it is determined that the intensity at the predetermined frequency exceeds the predetermined threshold value.

8. The processing termination detection apparatus according to claim 7, including:
a differentiator adapted to take a second-order derivative of the waveform of the received reflected light after the processing rate is changed;
a derivative value determination section adapted to determine whether a variation in a value of the second-order derivative falls within a predetermined range; and
a processing termination section adapted to stop processing on the to-be-processed layer when it is determined that the variation in the value of the second-order derivative falls within the predetermined range.

9. The processing termination detection apparatus according to claim 7, including:
a difference determinator adapted to take a second-order difference of the waveform of the received reflected light after the processing rate is changed;
a difference value determination section adapted to determine whether a variation in a value of the second-order difference falls within a predetermined range; and
a processing termination section adapted to stop processing on the to-be-processed layer when it is determined that the variation in the value of the second-order difference falls within the predetermined range.
